(19) United States
(12) Patent Application Publication
(10) Pub. No.: US 2026/0219874 A1
(43) Pub. Date: Jul. 30, 2026

(54) SEMICONDUCTOR DEVICE, METHOD FOR CONTROLLING SEMICONDUCTOR DEVICE, AND CONTROL PROGRAM

(71) Applicant: Renesas Electronics Corporation, Tokyo (JP)

(72) Inventors: Akira YONEKURA, Tokyo (JP); Kuniyasu TAJIMA, Tokyo (JP)

(21) Appl. No.: 19/411,735

(22) Filed: Dec. 8, 2025

(30) Foreign Application Priority Data
Jan. 28, 2025 (JP) 2025-011844

(51) Int. Cl. G06F 8/654; G06F 8/65; G06F 13/38

(52) U.S. Cl. CPC G06F 8/654; G06F 8/66; G06F 13/382

(57) ABSTRACT

To provide a semiconductor device, a control method for the semiconductor device, and a control program that can update the initial setting values of the interface circuit after a mask ROM is implemented. The semiconductor device includes an interface circuit, the mask ROM storing initial setting values and an initialization function, a CPU (Central Processing Unit) that sets the initial setting values in the interface circuit by executing the initialization function during initialization, and non-volatile memory. The initialization function stored in the mask ROM includes a patch function that updates the initial setting values set in the interface circuit during initialization using address information of the storage area to be accessed, data-related information, and processing-related information, which are written in the non-volatile memory.

### CROSS-REFERENCE TO RELATED APPLICATIONS

The disclosure of Japanese Patent Application No. 2025-011844 filed on January 28, 2025, including the specification, drawings and abstract is incorporated herein by reference in its entirety.

### BACKGROUND

The present disclosure relates to a semiconductor device, a control method for a semiconductor device, and a control program, specifically to a semiconductor device, a control method for a semiconductor device, and a control program that can update the initial setting values of an interface circuit after a mask ROM implementation.

With the development of connected and ADAS (Advanced Driver Assistance Systems) in the automotive field, many electronic devices such as in-vehicle cameras, drive recorders, and car navigation systems are installed in automobiles. Each electronic device requires advanced software, and the size of the storage that stores the software programs of each electronic device is also increasing.

There are disclosed techniques listed below.

[Patent Document 1] Japanese Unexamined Patent Application Publication No. 2000-293376

As a solution to reduce storage size, the automotive storage market is beginning to adopt UFS (Universal Flash Storage), which is advantageous in terms of capacity and performance (transfer speed) of NAND storage devices, instead of eMMC (Embedded Multi-Media-Card). By adopting UFS as a boot device, the number of components is reduced, and consequently, costs are lowered. Technology related to boot devices is disclosed, for example, in Patent Document 1.

### SUMMARY

Here, the boot ROM (Read Only Memory), which is part of the boot device, has initial setting values for interface circuits such as memory IF and communication IF written into it, and the initial setting values written into the boot ROM are called upon during initialization and set in the interface circuit. However, if the boot ROM is a mask ROM, the writing of initial setting values to the boot ROM is done before chip manufacturing (before boot ROM implementation) and cannot be done after chip manufacturing (after boot ROM implementation).

However, generally, the physical layer setting values of interface circuits such as memory IF and communication IF are setting values of device-specific parameters such as calibration values and are mostly determined by characteristic evaluation after chip manufacturing. Therefore, if the boot ROM is a mask ROM, accurate initial setting values cannot be written to the boot ROM before implementation, resulting in the inability to set accurate initial setting values in the interface circuit. Other objects and novel features will become apparent from the description of this specification and the accompanying drawings.

The semiconductor device according to the present disclosure includes an interface circuit, initial setting values, a mask ROM (Read Only Memory) storing initialization functions, a CPU (Central Processing Unit) that sets the initial setting values in the interface circuit by executing the initialization functions during initialization, and non-volatile memory. The initialization functions stored in the mask ROM include patch functions that update the initial setting values set in the interface circuit during initialization using address information of the storage area of the interface circuit to be accessed, information related to data, and information related to processing content, which are written in the non-volatile memory.

The control method for a semiconductor device according to the present disclosure includes an interface circuit, initial setting values, a mask ROM (Read Only Memory) storing initialization functions, a CPU (Central Processing Unit), and non-volatile memory. The CPU sets the initial setting values in the interface circuit by executing the initialization functions during initialization, and in setting the initial setting values in the interface circuit, The CPU reads address information of the storage area of the interface circuit to be accessed, information related to data, and information related to processing content, which are written in the non-volatile memory, and updates the initial setting values set in the interface circuit during initialization by executing patch functions included in the initialization functions using the information read from the non-volatile memory.

The control program according to the present disclosure is a control program that causes a computer to execute control processing of a semiconductor device equipped with an interface circuit, initial setting values, a mask ROM (Read Only Memory) storing initialization functions, and non-volatile memory. It causes the computer to execute processing to set the initial setting values in the interface circuit by executing the initialization functions during initialization, and in the processing to set the initial setting values in the interface circuit, it reads address information of the storage area of the interface circuit to be accessed, information related to data, and information related to processing content, which are written in the non-volatile memory, and updates the initial setting values set in the interface circuit during initialization by executing patch functions included in the initialization functions using the information read from the non-volatile memory.

The present disclosure can provide a semiconductor device, a control method for a semiconductor device, and a control program that can update the initial setting values of an interface circuit after mask ROM implementation.

### BRIEF DESCRIPTION OF THE DRAWINGS

FIG. 1 is a block diagram illustrating a configuration example of a semiconductor device according to a first embodiment.

FIG. 2 is a sequence diagram illustrating the operation during initialization of a semiconductor device according to the first embodiment.

FIG. 3 is a block diagram illustrating a configuration example of a semiconductor device according to a second embodiment.

FIG. 4 is a block diagram illustrating a configuration example of a semiconductor device at the conceptual stage.

FIG. 5 is a sequence diagram illustrating the operation during initialization of a semiconductor device at the conceptual stage.

### DETAILED DESCRIPTION

Below, the embodiments will be described with reference to the drawings. It should be noted that the drawings are simplified, and the technical scope of the embodiments should not be narrowly interpreted based on the descriptions in these drawings. Also, the same elements are denoted by the same reference numerals, and repetitive descriptions are omitted.

In the following embodiments, explanations may be divided into multiple sections or embodiments when necessary for convenience. However, unless specifically indicated otherwise, they are not unrelated to each other, and one is related to the other as a modified example, application example, detailed explanation, supplementary explanation, etc., in whole or in part. In the following embodiments, the number of elements, etc. (including the number of elements, numerical values, quantities, ranges, etc.) is not limited to the specific number, but may be not less than or equal to the specific number, except for cases where the number is specifically indicated and is clearly limited to the specific number in principle.

Furthermore, in the following embodiments, the constituent elements (including the operation steps and the like) are not necessarily essential except in the case where they are specifically specified and the case where they are considered to be obviously essential in principle. Similarly, in the following embodiments, when referring to the shapes, positional relationships, and the like of components and the like, it is assumed that the shapes and the like are substantially approximate to or similar to the shapes and the like, except for the case in which they are specifically specified and the case in which they are considered to be obvious in principle, and the like. The same applies to the above-mentioned numbers and the like, including the number, the numerical value, the amount, the range, and the like.

### Description of Semiconductor Device at the Conceptual Stage

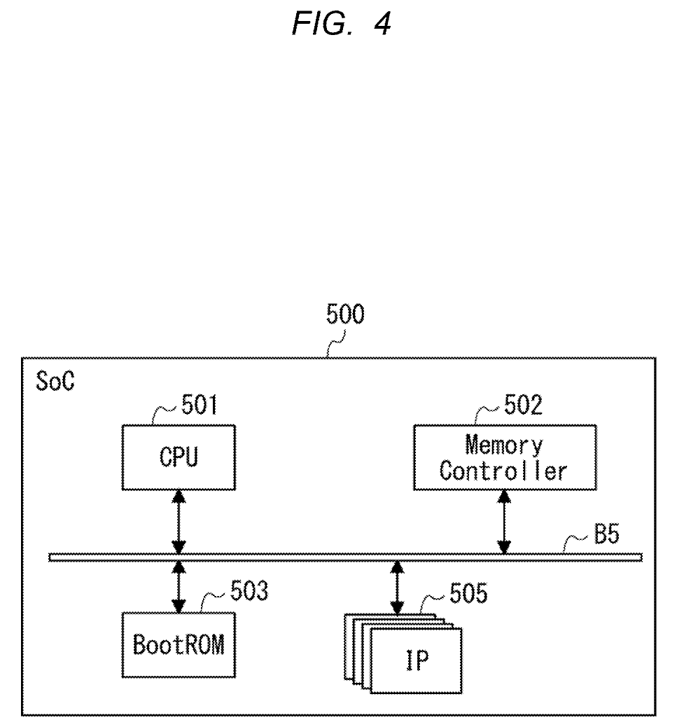

FIG. 4 is a block diagram illustrating a configuration example of semiconductor device 500 at the conceptual stage. The semiconductor device 500 is, for example, an SoC (System on Chip).

Specifically, semiconductor device 500 includes a CPU (Central Processing Unit) 501, a memory controller 502, a boot ROM 503, multiple other functional blocks (IP; Intellectual Property) 505, and a bus B5.

The CPU 501 is configured to access the memory controller 502, the boot ROM 503, and the IP 505 via the bus B5. The memory controller 502 manages access to memory (not shown) based on instructions from the CPU 501.

The boot ROM 503 is a mask ROM, which is a type of non-volatile memory. The boot ROM 503 has instruction codes, etc., written into it that the CPU 501 executes during initialization. Additionally, the boot ROM 503 has initial setting values for the memory controller 502 and initialization functions for setting initial setting values in the memory controller 502 by the CPU 501 written into it. These codes (data) are written before the boot ROM 503 is implemented in the semiconductor device 500 and cannot be changed after it is implemented.

For example, the CPU 501 sets initial setting values in the memory controller 502 by executing initialization functions called from the boot ROM 503 during initialization.

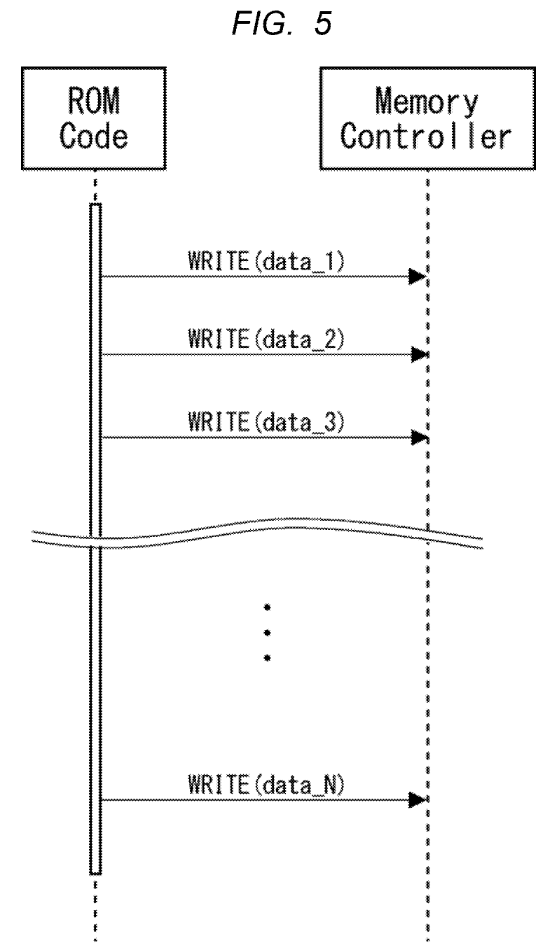

FIG. 5 is a sequence diagram illustrating the operation during initialization of the semiconductor device 500. In the semiconductor device 500, the CPU 501 performs initial settings for the memory controller 502 by executing initialization functions called from the boot ROM 503 during initialization. In the example of FIG. 5, the CPU 501 writes the setting values data_1 to data_N (N is an integer of 2 or more) read from the boot ROM 503 sequentially into the storage area of the memory controller 502 (storage area such as registers where initial setting values are stored).

Here, the initial setting values of the memory controller 502 are settings of device-specific parameters such as calibration values and are mostly determined by characteristic evaluation after chip manufacturing. Therefore, it is not possible to write accurate initial setting values into the boot ROM 503 before it is implemented in the semiconductor device 500. Therefore, the semiconductor device 500 cannot set accurate initial setting values in the memory controller 502.

Thus, a semiconductor device according to this disclosure has been found, which allows updating the initial setting values of interface circuits such as the memory controller even after the boot ROM is implemented.

### First Embodiment

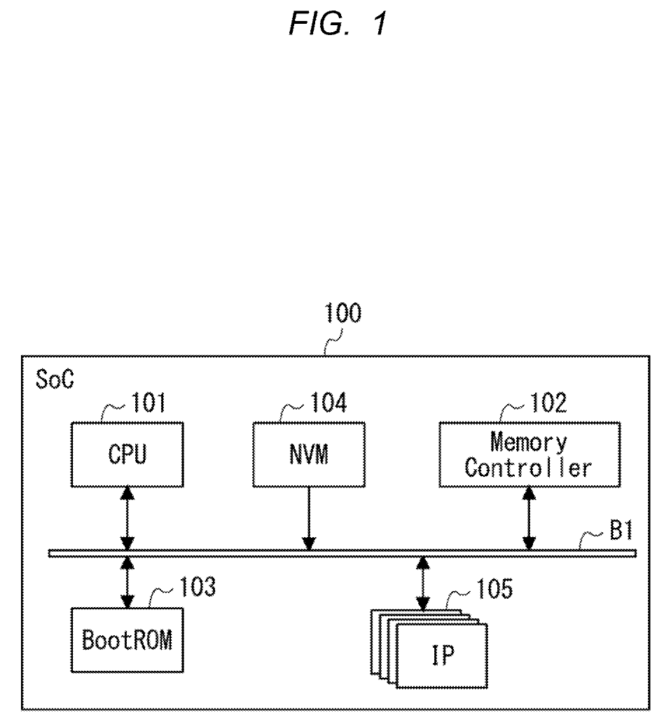

FIG. 1 is a block diagram showing a configuration example of a semiconductor device 100 according to the first embodiment. The semiconductor device 100 is, for example, an SoC (System on Chip).

Specifically, the semiconductor device 100 includes a CPU (Central Processing Unit) 101, a memory controller 102, a boot ROM (Read Only Memory) 103, a non-volatile memory (NVM) 104, multiple other functional blocks (IP; Intellectual Property) 105, and a bus B1.

The CPU 101 is configured to access the memory controller 102, the boot ROM 103, the NVM 104, and the IP 105 via the bus B1. The memory controller 102 manages access to a memory (not shown) based on instructions from the CPU 101. In other words, the memory controller 102 is an interface circuit that interfaces between processors such as the CPU 101 and a memory (not shown). The memory controller 102 is, for example, a UFS (Universal Flash Storage) controller.

The boot ROM 103 is a mask ROM (Read Only Memory), which is a type of non-volatile memory. The boot ROM 103 has instruction codes and the like written in it, which the CPU 101 executes during initialization. Additionally, the boot ROM 103 has initial setting values for the memory controller 102 and initialization functions for setting initial values in the memory controller 102 by the CPU 101 written in it. These codes (data) are written before the boot ROM 103 is implemented in the semiconductor device 100 and cannot be changed after being implemented in the semiconductor device 100.

Here, the initial setting values of the memory controller 102 are settings of device-specific parameters such as calibration values and are mostly determined by characteristic evaluation after chip manufacturing. Therefore, it is not possible to write accurate initial setting values into the boot ROM 103 before it is implemented in the semiconductor device 100.

Thus, a patch function for updating the initial setting values set in the memory controller 102 during initialization is further written into the boot ROM 103 as part of the initialization function. Details of the patch function will be described later.

The NVM 104 is, for example, an OTP (One-Time Programmable memory). The NVM 104 is configured to store data even after being implemented in the semiconductor device 100. Specifically, after the NVM 104 (and the boot ROM 103) is implemented in the semiconductor device 100, the NVM 104 is written with the address ADD of the storage area to be accessed within the storage area of the memory controller 102 (such as a register where initial setting values are stored), data DAT, and information CTL regarding the processing content.

For example, the CPU 101 sets the initial setting values in the memory controller 102 by executing the initialization function called from the boot ROM 103 during initialization. At this time, the CPU 101 updates the initial setting values set in the memory controller 102 by executing the patch function included in the initialization function using the address ADD, data DAT, and information CTL regarding the processing content read from the NVM 104.

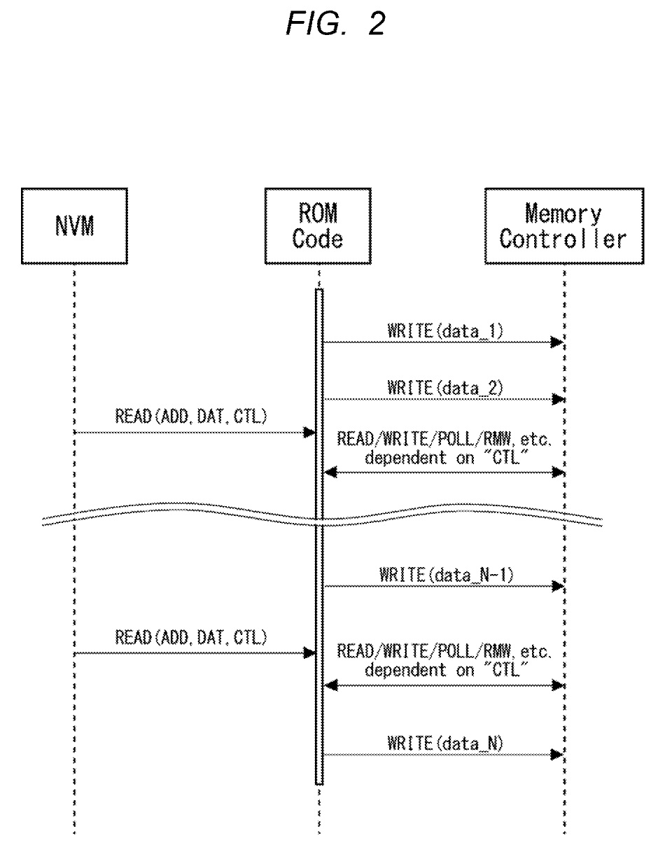

FIG. 2 is a sequence diagram showing the operation during initialization of the semiconductor device 100. First, after the boot ROM 103 is implemented in the semiconductor device 100, the NVM 104 is written with the address ADD of the storage area to be accessed within the storage area of the memory controller 102 (such as a register where initial setting values are stored), data DAT, and information CTL regarding the processing content.

Subsequently, the CPU 101 provided in semiconductor device 100 performs initial settings on the memory controller 102 by executing the initialization function called from the boot ROM 103 during initialization. In the example of FIG. 2, the CPU 101 writes the setting values data_1 to data_N (N is an integer of 2 or more) read from the boot ROM 103 sequentially into the storage area of the memory controller 102 (such as a register where initial setting values are stored).

Here, the CPU 101 updates the initial settings set in the memory controller 102 by executing the patch function included in the initialization function. In the example of FIG. 2, the CPU 101 reads the address ADD, data DAT, and information CTL regarding the processing content from the NVM 104 after writing the setting value data_2 to the memory controller 102 and after writing the setting value data_N-1 to the memory controller 102, respectively. Then, the CPU 101 updates the initial setting values set in the memory controller 102 by executing the patch function using the address ADD, data DAT, and information CTL regarding the processing content read from the NVM 102.

For example, if the processing content CTL read from the NVM 102 is “Read”, the CPU 101 reads data from the storage area specified by the address ADD within the storage area of the memory controller 102 and stores it in an internal variable register.

Also, if the processing content CTL read from the NVM 102 is “Write0”, the CPU 101 writes the data specified by the data DAT into the storage area specified by the address ADD within the storage area of the memory controller 102.

Also, if the processing content CTL read from the NVM 102 is “Write1”, the CPU 101 writes the data stored in the internal variable register (i.e., the data read by Read) into the storage area specified by the address ADD within the storage area of the memory controller 102.

Also, if the processing content CTL read from the NVM 102 is “Polling0”, the CPU 101 performs periodic checks until the data read from the storage area specified by the address ADD within the storage area of the memory controller 102 matches the data specified by the data DAT.

Also, if the processing content CTL read from the NVM 102 is “Polling1”, the CPU 101 performs periodic checks until the data read from the storage area specified by the address ADD within the storage area of the memory controller 102 no longer matches the data specified by the data DAT.

Also, if the processing content CTL read from the NVM 102 is “Get mask value”, the CPU 101 stores the data specified by the data DAT as a mask value for “Read Modify Write” in an internal variable register.

Also, if the processing content CTL read from the NVM 102 is “Read Modify Write”, the CPU 101 overwrites the logical OR C1 of the logical AND A1 of the data read from the storage area specified by the address ADD within the storage area of the memory controller 102 and the data (mask value) stored in the internal variable register by the “Get mask value” process, and the data B1 specified by the data DAT, into the storage area specified by the address ADD.

Note that the semiconductor device 100 can execute any processing content other than the above-mentioned processing content, and the processing content defined in CTL can be expanded beyond those mentioned above. It is also possible to include information on sequence numbers to determine when or whether to execute each batch process.

In this way, the semiconductor device 100 according to this disclosure can update the initial setting values of the memory controller 102 determined after the implementation of the boot ROM 103, after the boot ROM 103 is implemented. Specifically, the semiconductor device 100 according to this disclosure can write any data read from the NVM 102 into the storage area of any address read from the NVM 102. Also, the semiconductor device 100 according to this disclosure can execute any processing other than writing any data into the storage area of any address. As a result, the semiconductor device 100 according to this disclosure can set accurate initial setting values in the memory controller 102.

In this disclosure, the case where the semiconductor device 100 updates the initial setting values of the memory controller 102 after the implementation of the boot ROM 103 has been described as an example, but it is not limited thereto. The semiconductor device 100 can update the initial setting values of interface circuits other than the memory controller 102 after the implementation of the boot ROM 103. The method for updating the initial settings of interface circuits other than the memory controller 102 after the implementation of the boot ROM 103 is similar to the method for updating the initial settings of the memory controller 102 after the implementation of the boot ROM 103, so the explanation is omitted.

Interface circuits other than the memory controller 102 are circuits used for communication interfaces such as the UCIe (Universal Chiplet Interconnect Express) controller.

### Second Embodiment

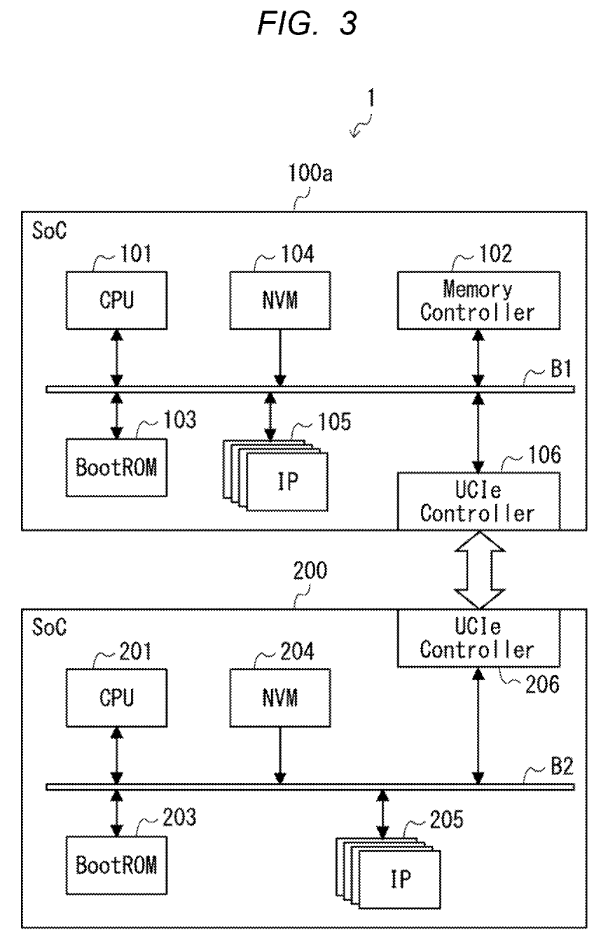

FIG. 3 is a block diagram showing an example configuration of a semiconductor system 1 provided with a semiconductor device 100a according to the second embodiment. The semiconductor system 1 includes a semiconductor device 100a and a semiconductor device 200. The semiconductor device 100a, compared to the semiconductor device 100, further includes a UCIe controller 106.

The semiconductor device 200 is, for example, an SoC. Specifically, semiconductor device 200 includes a CPU 201, a boot ROM 203, an NVM 204, a plurality of other functional blocks (IP) 205, a UCIe controller 206, and a bus B2. The CPU 201, the boot ROM 203, the NVM 204, the multiple IPs 205, the UCIe controller 206, and the bus B2 in the semiconductor device 200 correspond to the CPU 101, the boot ROM 103, the NVM 104, the multiple IPs 105, the UCIe controller 106, and the bus B1 in the semiconductor device 100, respectively.

The UCIe controller 106 of the semiconductor device 100a manages data communication between the semiconductor devices 100a and 200 together with the UCIe controller 206 of the semiconductor device 200.

Here, the boot ROM 103 has a patch function written as part of the initialization function to update the initial settings for the memory controller 102 and the UCIe controller 106 during initialization. Also, after the NVM 104 (and the boot ROM 103) is implemented in the semiconductor device 100a, the NVM 104 is written with the address ADD of the target storage area in the memory controller 102's storage area, data DAT, and information CTL regarding processing content. Similarly, the NVM 104 is written with the address ADD of the target storage area in the storage area of the UCIe controller 106, data DAT, and information CTL regarding processing content.

For example, the CPU 101 sets the initial values for the memory controller 102 and the UCIe controller 106 by executing the initialization function called from the boot ROM 103 during initialization. At this time, the CPU 101 updates the initial settings for the memory controller 102 and the UCIe controller 106 by executing the patch function included in the initialization function using the address ADD, data DAT, and information CTL regarding processing content read from the NVM 104.

Similarly, the boot ROM 203 has a patch function written as part of the initialization function to update the initial settings for the UCIe controller 206 during initialization. Also, after the NVM 204 (and the boot ROM 203) is implemented in the semiconductor device 200, the NVM 204 is written with the address ADD of the target storage area in the storage area of the UCIe controller 206, data DAT, and information CTL regarding processing content.

For example, the CPU 201 sets the initial values for the UCIe controller 206 by executing the initialization function called from the boot ROM 203 during initialization. At this time, the CPU 201 updates the initial settings for the UCIe controller 206 by executing the patch function included in the initialization function using the address ADD, data DAT, and information CTL regarding processing content read from the NVM 204.

Thus, the semiconductor device 100a according to this disclosure is not limited to updating the initial settings of the memory controller 102 but can also update the initial settings of circuits used for communication interfaces such as the UCIe controller 206 after the implementation of the boot ROM 103.

Although the invention made by the inventor has been specifically described based on the embodiment, the present invention is not limited to the embodiment already described, and it is needless to say that various modifications can be made without departing from the gist thereof.

This disclosure can be realized by having a CPU execute a computer program for part or all of the processing of the semiconductor devices 100 and 200.

The aforementioned program includes a set of instructions (or software code) for causing the computer to perform one or more functions described in the embodiment when loaded into the computer. The program may be stored in non-transitory computer-readable media or tangible storage media. By way of example and not limitation, computer-readable media or tangible storage media include RAM (Random-Access Memory), ROM (Read-Only Memory), flash memory, SSD (Solid-State Drive) or other memory technologies, CD-ROM, DVD (Digital Versatile Disc), Blu-ray (registered trademark) disc or other optical disc storage, magnetic cassette, magnetic tape, magnetic disk storage or other magnetic storage devices. The program may be transmitted on transitory computer-readable media or communication media. By way of example and not limitation, transitory computer-readable media or communication media include electrical, optical, acoustic, or other forms of propagated signals.

What is claimed is:

1. A semiconductor device comprising:
an interface circuit;
a mask ROM (Read Only Memory) for storing initial settings and initialization functions;
a CPU (Central Processing Unit) for setting the initial settings in the interface circuit by executing the initialization functions during initialization; and
a non-volatile memory,
wherein the initialization functions stored in the mask ROM includes a patch function that updates the initial settings set in the interface circuit during initialization using address information of the target storage area, data information, and processing content information written in the non-volatile memory.

2. The semiconductor device according to claim 1,
wherein the non-volatile memory is configured to store the address information, data information, and process content information after the implementation of the mask ROM.

3. The semiconductor device according to claim 1,
wherein the non-volatile memory is an OTP (One-Time Programmable memory).

4. The semiconductor device according to claim 1,
wherein the interface circuit is a memory controller.

5. The semiconductor device according to claim 1,
wherein the interface circuit is a UFS (Universal Flash Storage) controller.

6. The semiconductor device according to claim 1,
wherein the interface circuit is a circuit used for communication interfaces.

7. The semiconductor device according to claim 6,
wherein the interface circuit is a UCIe (Universal Chiplet Interconnect Express) controller.

8. A control method for a semiconductor device comprising an interface circuit, initial settings, an initialization function stored in a mask ROM (Read Only Memory), a CPU (Central Processing Unit), and non-volatile memory,
wherein the CPU sets the initial settings in the interface circuit by executing the initialization function during initialization, and in setting the initial settings in the interface circuit, the CPU reads address information of the target storage area, data information, and processing content information written in the non-volatile memory, and updates the initial settings set in the interface circuit during initialization by executing the patch function included in the initialization function using the information read from the non-volatile memory.

9. The control method according to claim 8,
wherein the non-volatile memory is written with address information, data information, and processing content information after the implementation of the mask ROM in the semiconductor device.

10. A control program that enables a computer to execute control processing of a semiconductor device comprising an interface circuit, initial setting values, an initialization function stored in a mask ROM (Read Only Memory), and non-volatile memory,
wherein the computer executes the process of setting the initial setting values in the interface circuit by executing the initialization function during initialization,
wherein the computer reads address information of the storage area to be accessed, data-related information, and processing-related information, which are written in the non-volatile memory, in the process of setting the initial setting values in the interface circuit,
wherein the computer executes a patch function included in the initialization function using the information read from the non-volatile memory and updates the initial setting values set in the interface circuit during initialization.

11. The control program according to claim 10,
the non-volatile memory is written with address information, data-related information, and processing-related information after the mask ROM is implemented in the semiconductor device.
